(19) United States
(12) Patent Application Publication
(10) Pub. No.: US 2014/0315134 A1
(43) Pub. Date: Oct. 23, 2014

(54) METHOD AND APPARATUS FOR MANUFACTURING DONOR SUBSTRATE

(71) Applicant: Samsung Display Co., Ltd., Yongin-City (KR)

(72) Inventors: Hyun Sung BANG, Yongin-si (KR); Won Jong KIM, Yongin-si (KR); Ji Young CHOUNG, Yongin-si (KR); Joon Gu LEE, Yongin-si (KR); Jin Baek CHOI, Yongin-si (KR); Yeon Hwa LEE, Yongin-si (KR)

(21) Appl. No.: 14/072,272

(22) Filed: Nov. 5, 2013

(30) Foreign Application Priority Data
Apr. 17, 2013 (KR) 10-2013-0042342

(51) Int. Cl. G03F 7/00

(52) U.S. Cl. CPC G03F 7/0035
USPC 430/324

(57) ABSTRACT

In a method and apparatus for manufacturing a donor substrate, a pattern layer which exposes a surface of a substrate is arranged on the substrate, and an organic material is deposited on the exposed surface of the substrate. The pattern layer includes a film pattern that defines a plurality of first openings and a photoresist pattern that is positioned on the film pattern and defines second openings, which correspond to the first openings, respectively, a minimum width of the second openings being smaller than that of the first openings.

This application makes reference to, incorporates into this specification the entire contents of and claims all benefits accruing under 35 U.S.C. §119 from an application earlier filed in the Korean Intellectual Property Office on Apr. 17, 2013 and there duly assigned Serial No. 10-2013-0042342.

### BACKGROUND OF INVENTION

1. Field of the Invention

The present invention relates to a method and an apparatus for manufacturing a donor substrate.

2. Description of the Prior Art

In the case of forming various patterns on a substrate that is included in a semiconductor, display devices, and solar cells, the patterns may be directly formed on the substrate, or the patterns may be indirectly formed on another substrate and then may be transferred to the target substrate. Here, the other substrate may be a donor substrate. That is, the donor substrate may be a substrate which is used to form various patterns on the substrate that is included in the semiconductor, display devices, and solar cells.

In the above-described transfer process, it is necessary to manufacture such a donor substrate in advance. That is, various patterns can be formed on the substrate that is included in the semiconductor, display devices, and solar cells by transporting the donor substrate, which is manufactured in advance, to a transfer target substrate.

There are various methods for manufacturing such a donor substrate. For example, the donor substrate may be manufactured by a deposition process. The donor substrate may include a substrate that is included in the semiconductor, display devices, and solar cells, i.e., a transfer layer that is transferred to a transfer target substrate, and this transfer layer may also be formed by the deposition process. The transfer layer may receive various types of energy in a desired pattern shape in a state where the transfer layer is not patterned, and the pattern may be transferred to the transfer target substrate.

### SUMMARY OF THE INVENTION

As described above, in the case where the pattern is formed on the transfer target substrate by transferring a non-patterned transfer layer, the transfer layer may be transferred as it tears, and this causes an edge inferiority of the pattern to occur. Furthermore, since it is difficult to accurately transfer specific energy with a desired shape, the pattern may not be finely formed.

Accordingly, one subject to be solved by the present invention is to provide a method for manufacturing a donor substrate which includes a fine organic film pattern that is formed using a film pattern and a photoresist pattern.

Another subject to be solved by the present invention is to provide a method for manufacturing a donor substrate which forms a film pattern and a photoresist pattern by a successive in-line process, and which forms a fine organic film pattern on a substrate using the film pattern and the photoresist pattern.

Additional advantages, subjects, and features of the present invention will be set forth in part in the description which follows, and in part will become apparent to those having ordinary skill in the art upon examination of the following or may be learned from practice of the present invention.

In one aspect of the present invention, there is provided a method for manufacturing a donor substrate, comprising arranging a pattern layer, which exposes a surface of a substrate, on the substrate, and depositing an organic material on the exposed surface of the substrate, wherein the pattern layer includes a film pattern that defines a plurality of first openings and a photoresist pattern that is positioned on the film pattern and defines second openings, which correspond to the first openings, respectively, and a minimum width of which is smaller than that of the first openings.

In another aspect of the present invention, there is provided a method for manufacturing a donor substrate, comprising forming a pattern layer which includes a film pattern that defines a plurality of openings and a photoresist pattern that is positioned on the film pattern and is in an inverse tapered shape, arranging the pattern layer on a substrate, and depositing an organic material on a surface of the substrate which is exposed by the pattern layer.

In still another aspect of the present invention, there is provided an apparatus for manufacturing a donor substrate, comprising a first patterning portion forming a film pattern that defines a plurality of first openings, a second patterning portion forming a photoresist pattern that is positioned on the film pattern and defines second openings which correspond to the first openings, respectively, and a minimum width of which is smaller than that of the first openings.

According to the embodiments of the present invention, at least the following effects can be achieved.

That is, by manufacturing the donor substrate that includes the fine organic film pattern, the fine pattern can be formed on the transfer target substrate.

Furthermore, after the organic film pattern is formed, the pattern layer can be removed without damage to the organic film pattern.

Furthermore, since the film pattern is made of a plastic material that is light and has high ductility and elasticity, the film pattern can be easily processed, and it is easy to handle the film pattern since its shape deformation is small.

Furthermore, since the organic material is deposited on the substrate in a state where the film pattern comes in contact with one surface of the substrate, substrate drooping does not occur, and thus the organic film pattern can be stably formed.

Furthermore, since the pattern layer is formed by the successive in-line process and the organic film pattern is formed on the substrate using the pattern layer, the overall processing loss can be reduced.

Furthermore, since it is easy to change the minimum width of the opening that is defined by the photoresist pattern by adjustment of the shape of the photoresist pattern, for example, by adjustment of an angle that is formed between one surface of the film pattern and the side surface of the photoresist pattern, the organic film pattern with various sizes can be manufactured in a single manufacturing line.

The effects according to the present invention are not limited to the contents as exemplified above, but various additional effects are described in the specification of the present invention.

### BRIEF DESCRIPTION OF THE DRAWINGS

The above and other objects, features and advantages of the present invention will be more apparent from the following detailed description taken in conjunction with the accompanying drawings, in which:

FIG. 1 is a planar view illustrating an arrangement of a pattern layer on a substrate in a method for manufacturing a donor substrate according to an embodiment of the present invention;

FIG. 2 is a cross-sectional view taken along line II-II of FIG. 1;

FIG. 3 is a planar view illustrating forming of an organic film pattern on a surface of a substrate in a method for manufacturing a donor substrate according to an embodiment of the present invention;

FIG. 4 is a cross-sectional view taken along line IV-IV of FIG. 3;

FIG. 5 is a cross-sectional view of a donor substrate manufactured according to a method for manufacturing a donor substrate according to an embodiment of the present invention;

FIG. 6 is a cross-sectional view illustrating an arrangement of a base film on a laser portion in a method for manufacturing a donor substrate according to an embodiment of the present invention;

FIG. 7 is a cross-sectional view illustrating formation of a film pattern by irradiating a base film with laser in a method for manufacturing a donor substrate according to an embodiment of the present invention;

FIG. 8 is a cross-sectional view illustrating an arrangement of a film pattern on an auxiliary film in a method for manufacturing a donor substrate according to an embodiment of the present invention;

FIG. 9 is a cross-sectional view illustrating formation of a photoresist layer on a film pattern in a method for manufacturing a donor substrate according to an embodiment of the present invention;

FIG. 10 is a cross-sectional view illustrating exposure of a photoresist film in a method for manufacturing a donor substrate according to an embodiment of the present invention;

FIG. 11 is a cross-sectional view illustrating formation of a photoresist pattern by developing an exposed photoresist layer in a method for manufacturing a donor substrate according to an embodiment of the present invention;

FIG. 12 is a cross-sectional view illustrating a pattern layer, from which an auxiliary film is separated in a method for manufacturing a donor substrate according to an embodiment of the present invention;

FIG. 13 is a planar view illustrating an arrangement of a pattern layer on a substrate in a method for manufacturing a donor substrate according to another embodiment of the present invention;

FIG. 14 is a planar view illustrating formation of an organic film pattern on a surface of a substrate in a method for manufacturing a donor substrate according to another embodiment of the present invention;

FIG. 15 is a planar view illustrating an arrangement of a pattern layer on a substrate in a method for manufacturing a donor substrate according to still another embodiment of the present invention;

FIG. 16 is a planar view illustrating formation of an organic film pattern on a surface of a substrate in a method for manufacturing a donor substrate according to still another embodiment of the present invention;

FIG. 17 is a planar view illustrating an arrangement of a pattern layer on a substrate in a method for manufacturing a donor substrate according to still another embodiment of the present invention;

FIG. 18 is a planar view illustrating formation of an organic film pattern on a surface of a substrate in a method for manufacturing a donor substrate according to still another embodiment of the present invention;

FIG. 19 is a planar view illustrating an arrangement of a pattern layer on a substrate in a method for manufacturing a donor substrate according to still another embodiment of the present invention;

FIG. 20 is a planar view illustrating formation of an organic film pattern on a surface of a substrate in a method for manufacturing a donor substrate according to still another embodiment of the present invention; and

FIG. 21 is a conceptual view schematically illustrating an apparatus for manufacturing a donor substrate according to an embodiment of the present invention.

### DETAILED DESCRIPTION OF THE INVENTION

The aspects and features of the present invention and methods for achieving the aspects and features will be apparent by referring to the embodiments to be described in detail with reference to the accompanying drawings. However, the present invention is not limited to the embodiments disclosed hereinafter, but can be implemented in diverse forms. The matters defined in the description, such as the detailed construction and elements, are nothing but specific details provided to assist those of ordinary skill in the art in a comprehensive understanding of the present invention, and the present invention is only defined within the scope of the appended claims.

The term “on” that is used to designate that an element is on another element or located on a different layer or a layer includes both a case where an element is located directly on another element or a layer and a case where an element is located on another element via another layer or still another element. In the entire description of the present invention, the same drawing reference numerals are used for the same elements throughout various figures.

Although the terms “first, second, and so forth” are used to describe diverse constituent elements, such constituent elements are not limited by the terms. The terms are used only to discriminate a constituent element from other constituent elements. Accordingly, in the following description, a first constituent element may be a second constituent element.

“Donor substrates 100, 101, 102, 103, and 104” described in the description may be substrates which are used to form various patterns on substrates that are included in semiconductor, display devices, and solar cells. In exemplary embodiments, the “donor substrates 100, 101, 102, 103, and 104” may include transfer layers composed of organic materials, and the transfer layers may be transferred onto the substrates included in the semiconductor, display devices, and solar cells by an LITI (Laser Induced Thermal Imaging) method, a JICP (Joule-heating Induced Color Patterning) method, an LIPS (Laser Induced Pattern-wise Sublimation) method, an RIST (Radiation Induced Sublimation Transfer) method, or the like. In the following description, it is assumed that the “donor substrates 100, 101, 102, 103, and 104” are substrates which are used to form patterns that are composed of organic materials on display substrates included in the display devices, but are mot limited thereto.

Hereinafter, preferred embodiments of the present invention will be described with reference to the accompanying drawings.

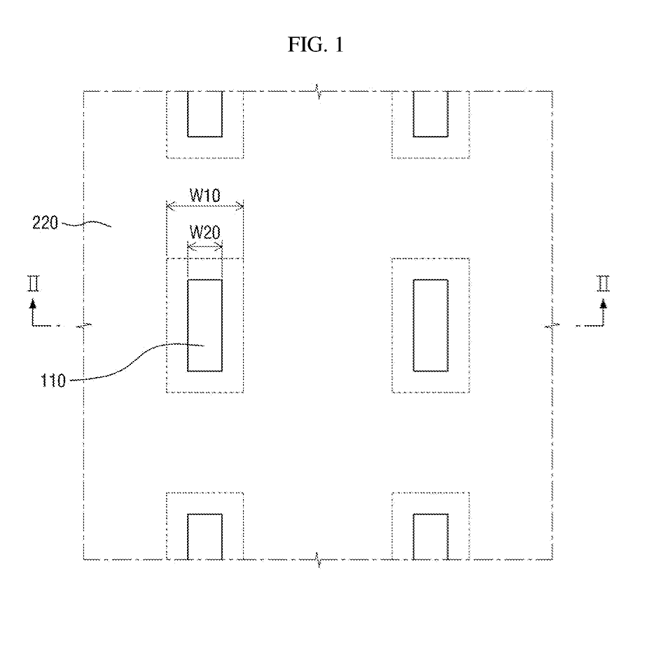

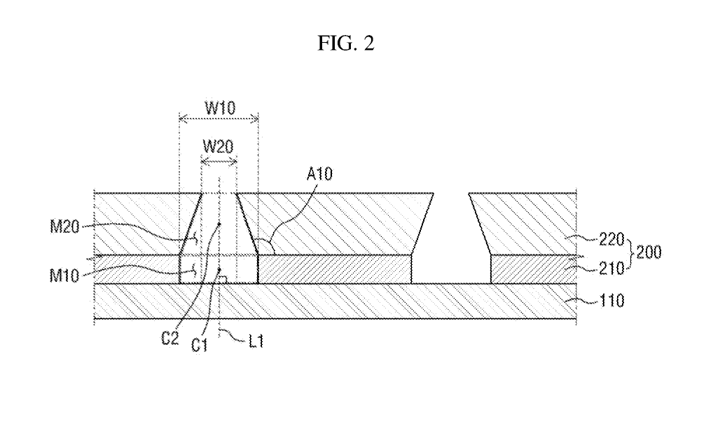

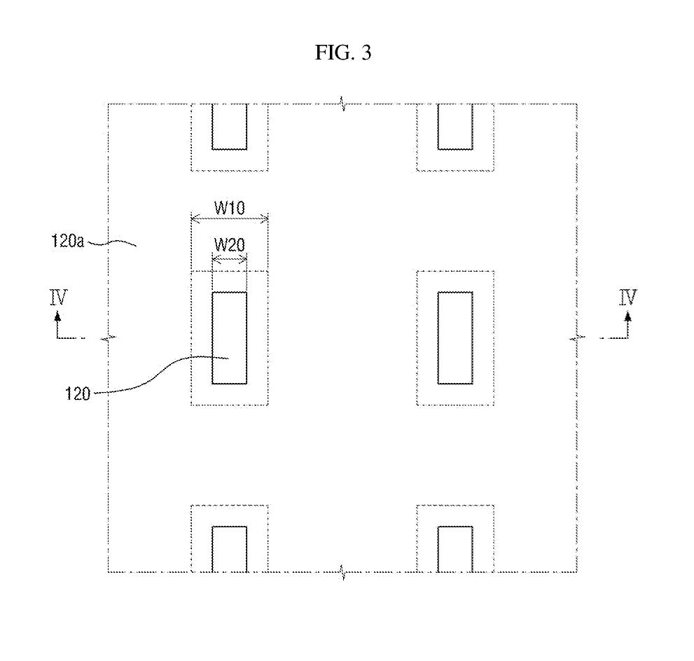

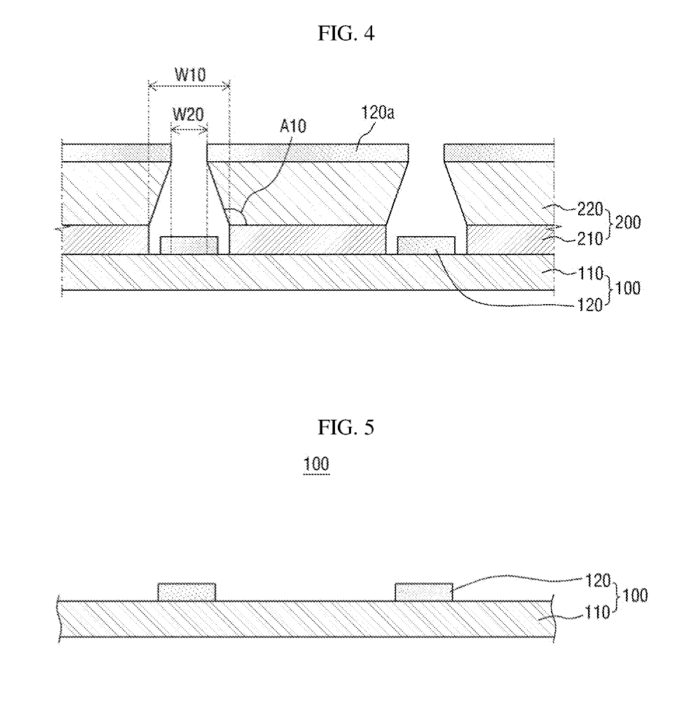

FIG. 1 is a planar view illustrating an arrangement of a pattern layer on a substrate in a method for manufacturing a donor substrate 100 according to an embodiment of the present invention. FIG. 2 is a cross-sectional view taken along line II-II of FIG. 1. FIG. 3 is a planar view illustrating forming of an organic film pattern on a surface of a substrate in a method for manufacturing a donor substrate according to an embodiment of the present invention. FIG. 4 is a cross-sectional view taken along line IV-IV of FIG. 3. FIG. 5 is a cross-sectional view of a donor substrate manufactured according to a method for manufacturing a donor substrate according to an embodiment of the present invention. Referring to FIGS. 1 to 5, a method for manufacturing a donor substrate 100 according to an embodiment of the present invention may include arranging a pattern layer 200 that exposes a surface of a substrate 110, and depositing an organic material on the exposed surface of the substrate 110.

First, referring to FIGS. 1 and 2, the method for manufacturing a donor substrate 100 according to an embodiment of the present invention may include arranging the pattern layer 200 that exposes the surface of the substrate 110.

The substrate 110 may be the donor substrate 100 on which the organic material is not deposited. That is, the substrate 110 may be the donor substrate 100 that does not include an organic film pattern 120.

The substrate 110 may be in a cuboidal plate shape, but is not limited thereto. The substrate may be in various shapes including that og a circular plate. Furthermore, the surface of the substrate 110 may be flat, but is not limited thereto. The surface of the substrate 110 may be curved. In an exemplary embodiment of the present invention, the shape of the surface of the substrate 110 may correspond to, for example, the shape of the surface of a display substrate.

The substrate 110 may include at least one inorganic film, at least one organic film, at least one organic/organic film, or a laminated film including a combination of the above-described films. In an exemplary embodiment of the present invention, the substrate 110 may include a single film composed of an inorganic film, for example, a metal film or a glass film, but is not limited thereto. The substrate 110 may include a single film composed of an organic film, or a multi-film in which an inorganic film and an organic film are alternately laminated.

The substrate 110 may be made of a material or a structure, which can transfer or convert energy. In an exemplary embodiment of the present invention, the substrate 110 may include metal having high thermal conductivity, for example, silver, copper, aluminum, or a combination thereof. In another exemplary embodiment of the present invention, the substrate 110 may include a thermal resistance line, and electric energy may be converted into thermal energy by the thermal resistance line. In still another exemplary embodiment of the present invention, the substrate 110 may be made of a transparent material, and light that is irradiated onto one surface of the substrate 110 may penetrate the substrate to transfer light energy.

Although not illustrated in the drawing, the substrate 110 may include a base layer, a light-heat conversion layer, an intermediate layer, and a buffer layer.

The base layer is made of transparent polymer, and the polymer may be polyester, such as polyethylene terephthalate, polyacryl, poly epoxy, polyethylene, or polystyrene. Among them, a polyethylene terephthalate film is mainly used. The base layer should have an optical property and a mechanical stability as a support film. It is preferable that the thickness of the base layer is 10 to 100

The light-heat conversion layer may be positioned on the base layer. The light-heat conversion layer may be a layer which absorbs light of an infrared-visual light region and converts a part of the light into heat. The light-heat conversion layer may have optical density and may include a light absorption material. The light-heat conversion layer may be, for example, a metal film that includes aluminum oxide or aluminum sulfide as the light absorption material, or a polymer organic film that includes carbon black, graphite, or infrared dye as the light absorption material. In this case, it is preferable that the metal film be formed with a thickness of 100 to 5,000 Å using a vacuum deposition method, an electron beam deposition method, or a sputtering method, and the organic film is formed with a thickness of 0.1 to 10 μm using roll coating that is a general film coating method, gravure, extrusion, spin, or knife coating method.

The intermediate layer may be positioned on the light-heat conversion layer. The intermediate layer may serve to prevent the light absorption material included in the light-heat conversion layer, for example, carbon black, from polluting a layer that is formed in the subsequent process. The intermediate layer may be formed of acrylic resin or alkyd resin. The formation of the intermediate layer is performed by a general coating process, such as solvent coating, and a curing process, such as a UV curing process.

The buffer layer may be positioned on the intermediate layer. The buffer layer may be formed so as to prevent the damage of a layer that is formed on the buffer layer and so as to effectively adjust an adhesive force of a layer that is formed on the intermediate layer and the buffer layer. The buffer layer may include at least one of an insulating material, metal, and metal oxide.

The pattern layer 200 may include a film pattern 210 and a photoresist pattern 220 that is positioned on the film pattern 210.

The film pattern 210 may be made of plastic. In an exemplary embodiment of the present invention, the film pattern 210 may be made of polyester, polyacryl, poly epoxy, polyethylene, polystyrene, polyamide, polyacetal, acryl, polybuthylene terephthalate, polycarbonate, or a combination thereof, but is not limited thereto. As described above, the film pattern 210 that is composed of plastic does not have high heat denaturation, and thus can be easily processed by laser or the like.

The film pattern 210 may be made of a material having high ductility and/or elasticity. That is, the film pattern 210 may be made of a material which can be easily restored to the original shape even if an external force, such as a tensile force, is applied thereto. In an exemplary embodiment of the present invention, the film pattern 210 may be made of fiber-reinforced plastics (FRP), for example, glass fiber-reinforced plastics or carbon fiber-reinforced plastics, but is not limited thereto. As described above, the film pattern 210 that is made of a material having high ductility and/or elasticity can keep the original shape even if rolling, folding, or bending of the film pattern 210 occurs during a process of manufacturing the donor substrate 100.

The film pattern 210 may define a plurality of first openings M10. That is, the film pattern 210 may include a plurality of first openings M10. Here, the first opening M10 may be a space that is surrounded by the film pattern 210. Specifically, if the pattern layer 200 is arranged on the substrate 110, the first opening M10 may be a space that is surrounded by the substrate 110, the film pattern 210, and a second opening M20. In an exemplary embodiment of the present invention, the plurality of first openings M10 may be arranged in a matrix form, but the invention is not limited thereto. Furthermore, the plurality of first openings M10 may be formed so as to be spaced apart from each other at predetermined intervals, but the invention is not limited thereto. The plurality of first openings M10 may be formed so as to be spaced apart from each other at different intervals. Furthermore, the size of the plurality of first openings M10 may be the same, but the invention is not limited thereto. The size of some of the first openings M10 may be different from the size of the remaining first openings M10. In a planar view, the shape of the plurality of first openings M10 may be a rectangle, but the invention is not limited thereto. The shape of the first openings M10 may be a polygon, a circle, or an ellipse.

The film pattern 210 may expose the surface of the substrate 110 through the plurality of first openings M10. The surface of the exposed substrate 110 may correspond to the shape of the first openings M10. In an exemplary embodiment of the present invention, if the shape of the first opening M10 as seen from a planar view is a rectangle, the shape of the surface of the exposed substrate 110 may also be a rectangle. In another exemplary embodiment of the present invention, if the shape of the first opening M10 as seen from the planar view is a circle, the shape of the surface of the exposed substrate 110 may also be a circle.

The first opening M10 that is defined by the film pattern 210 may have a first width W10. In an exemplary embodiment of the present invention as illustrated in the drawings, the first opening M10 may have the first width W10, and the first width W10 may be the minimum width of the first opening M10. That is, the shape of the first opening M10 in the planar view may be a rectangle, the length of a short side of the rectangle may be the first width W10, and the first width W10 may be the minimum width of the first opening M10.

The photoresist pattern 220 may be made of photoresist. In an exemplary embodiment of the present invention, the photoresist pattern 220 may be made of negative photoresist including, for example, an ethylenically unsaturated compound having an ethylenically unsaturated bond and UV-curable composition including photopolymerization initiators, but the invention is not limited thereto. That is, the kinds of photoresist that form the photoresist pattern 220 are not limited. More specifically, the photoresist pattern 220 according to the present invention can be implemented using all UV-curable materials which have been currently developed and commercialized or which can be implemented according to technical development in the future. In other words, the scope of the present invention is not limited by the kinds of photoresist.

The photoresist pattern 220 may define a plurality of second openings M20. That is, the photoresist pattern 220 may include a plurality of second openings M20. Here, the second opening M20 may mean a space surrounded by the photoresist pattern 220. Specifically, if the pattern layer 200 is arranged on the substrate 110, the second opening M20 may mean a space that is surrounded by the first opening M10 and the photoresist pattern 220.

The photoresist pattern 220 can expose the surface of the substrate 110 through the plurality of second openings M20. The surface of the exposed substrate 110 may correspond to the shape of the second opening M20. In an exemplary embodiment of the present invention, if the shape of the second opening M20 as seen from the planar view is a rectangle, the shape of the surface of the exposed substrate 110 may also be a rectangle. In another exemplary embodiment of the present invention, if the shape of the second opening M20 as seen from the planar view is a circle, the shape of the surface of the exposed substrate 110 may also be a circle.

The second opening M20 that is defined by the photoresist pattern 220 may have a second width W20. In an exemplary embodiment of the present invention illustrated in the drawings, the second opening M20 may have the second width W20, and the second width W20 may be the minimum width of the second opening M20. That is, the shape of the second opening M20 in the planar view may be a rectangle, the length of a short side of the rectangle may be the second width W20, and the second width W20 may be the minimum width of the second opening M20.

The minimum width of the second opening M20 that is defined by the photoresist pattern 220, for example, the second width W20, may be smaller than the minimum width of the first opening M10 that is defined by the film pattern 210, that is, the first width W10. Specifically, the second width W20 may be ⅘ to ⅖ of the first width W10.

The second opening M20 that is defined by the photoresist pattern 220 may correspond to the first opening M10. In an exemplary embodiment of the present invention, the second opening M20 may completely overlap the first opening M10. That is, an area in which the second opening M20 is vertically projected onto the substrate 110 may be equal to an area in which the first opening M10 is vertically projected onto the substrate 110. Furthermore, a line that connects a center C1 of the first opening M10 and a center C2 of the second opening M20 to each other, that is, a center line L1, may be perpendicular to the surface of the substrate 110. Furthermore, the shape of the first opening M10 and the shape of the second opening M20 may be substantially the same. Furthermore, both the shape of the first opening M10 and the shape of the second opening M20 may be a rectangle. Furthermore, the area in which the second opening M20 having the minimum width is vertically projected onto the substrate 110 may be positioned on an inner side than the boundary of the first opening M10. Furthermore, the area in which the second opening M20 having the minimum width is vertically projected on the substrate 110 may be spaced apart from the film pattern 210. The second opening M20 having the minimum width may be a portion having the minimum width in the second opening M20. In an exemplary embodiment of the present invention illustrated in FIG. 2, the second opening M20 having the minimum width may be a part of the second opening M20 that is positioned on the same plane as the upper surface of the photoresist pattern 220.

At least a part of the photoresist pattern 220 may overlap the film pattern 210. Furthermore, the film pattern 210 may completely overlap the photoresist pattern 220. In an exemplary embodiment of the present invention, the center portion of the photoresisto pattern 220 may overlap the film pattern 210, but the edge portion of the photoresist pattern 220 may not overlap the film pattern 210. That is, the edge portion of the photoresist pattern 220 may project in the center line direction. In an exemplary embodiment of the present invention illustrated in the drawings, a distance in which the photoresist pattern 220 projects may be increased as the photoresist pattern 220 goes far from the substrate 110, but the invention is not limited thereto.

The lower surface of the photoresist pattern 220 may completely overlap the upper surface of the film pattern 210. That is, the lower surface of the photoresist pattern 220 may come into contact with the upper surface of the film pattern 210, and the lower surface of the photoresist pattern 220 that is exposed to an outside or the upper surface of the film pattern 210 may not exist.

The shape of the photoresist pattern 220 may be an inverse tapered shape. That is, the width of the photoresist pattern 220 may be gradually smaller as the photoresist pattern 220 extends to the direction of the substrate 110. In other words, the area of the lower surface of the photoresist pattern 220 may be larger than the area of the upper surface thereof. In a cross-sectional view, the shape of the photoresist pattern 220 may be an inverse-shaped trapezoid. As a result of the shape of the photoresist pattern 220 as described above, the shape of the second opening M20 may be a trapezoid in the cross-sectional view. Furthermore, since the photoresist pattern 220 is in the inverse-shaped trapezoidal shape, the minimum width of the second opening M20 may be measured on a plane that is surrounded by upper end corners of the photoresist pattern 220. Furthermore, an angle that is formed between the side surface of the photoresist pattern 220 and one surface of the film pattern 210, for example, a first angle A10, may be 90 to 180 degrees. However, the shape of the photoresist pattern 220 according to this embodiment of the present invention is not limited to the inverse tapered shape. That is, the shape of the photoresist pattern 220 according to this embodiment of the present invention may include all the shapes of the photoresist pattern 220 which defines the second opening M20 having a minimum width that is smaller than the minimum width of the first opening M10.

As described above, the pattern layer 200 that includes the film pattern 210 and the photoresist pattern 220 may be arranged on the substrate 110. That is, the pattern layer 200 may be aligned on the substrate 110 so that the surface of the substrate 110, on which the organic film pattern 120 is to be formed, is exposed.

Next, referring to FIGS. 3 and 4, the method for manufacturing a donor substrate 100 according to an embodiment of the present invention may include depositing an organic film pattern 120 on the surface of the exposed substrate 110 after arranging the pattern layer 200 that exposes the surface of the substrate 110. That is, the organic film pattern 120 may be formed on the exposed surface of the substrate 110.

The organic film pattern 120 may be substantially a transfer target substrate, for example, a transfer layer that is transferred to the display substrate. Accordingly, the organic film pattern 120 may be made of the same material as the material of the pattern that is intended to be formed on the transfer target substrate. Furthermore, if the substrate 110 includes a buffer layer or an intermediate layer, the organic film pattern 120 may be formed on the buffer layer or the intermediate layer. Furthermore, the organic film pattern 120 may be formed on one surface of the substrate 110 that faces the transfer target substrate. Furthermore, since the organic film pattern 120 may be radially transferred or sublimated onto the transfer target substrate, the organic film pattern 120 may have a width that is smaller than the width of the pattern that is intended to be formed on the transfer target substrate.

The width of the organic film pattern 120 may be larger than the minimum width of the second opening M20, and may be smaller than the minimum width of the first opening M10. In an exemplary embodiment of the present invention illustrated in the drawings, the width of the organic film pattern 120 may be larger than the minimum width of the second opening M20, that is, the second width W20, and may be smaller than the minimum width of the first opening M10, that is, the first width W10. Furthermore, the organic film pattern 120 may be positioned in the center portion of the surface of the substrate 110 that is exposed by the film pattern 210. That is, the organic film pattern 120 may be surrounded by the film pattern 210, but may be spaced apart from the film pattern 210. Furthermore, the organic film pattern 120 may be included in the first opening M10. In an exemplary embodiment of the present invention illustrated in the drawings, the organic film pattern 120 is included only in the first opening M10, but is not limited thereto. If the deposition processing time is increased, the thickness of the organic film pattern 120 becomes thicker, and a part of the organic film pattern 120 may be included in the second opening M20.

When the organic film pattern 120 is formed, a sacrificial organic film pattern 120a may be simultaneously formed on the film pattern 210. The sacrificial organic film pattern 120a is not included in the donor substrate 100, and may be removed when the pattern layer 200 is subsequently removed. The sacrificial organic film pattern 120a may be made of the same material as the organic film pattern 120. Furthermore, the sacrificial organic film pattern 120a may be formed with the same thickness as the organic film pattern 120, or may be formed with different thicknesses depending on the processing conditions.

By removing the pattern later 200 after the organic film pattern 120 is formed on the exposed surface of the substrate 110, the donor substrate 100 can be completed as illustrated in FIG. 5.

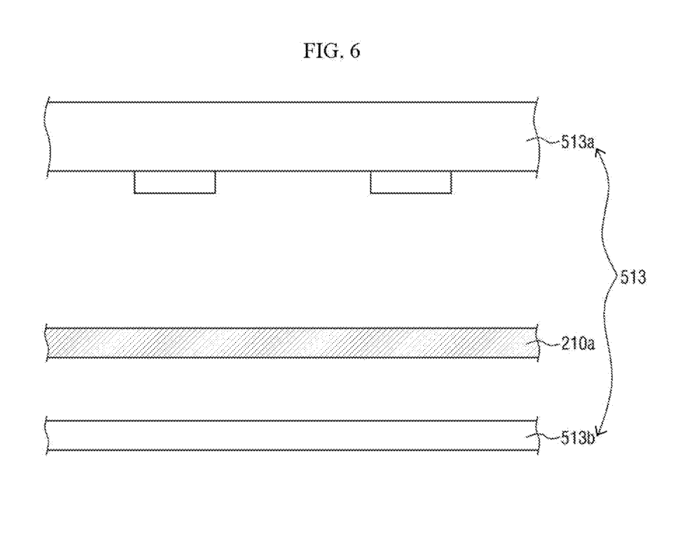

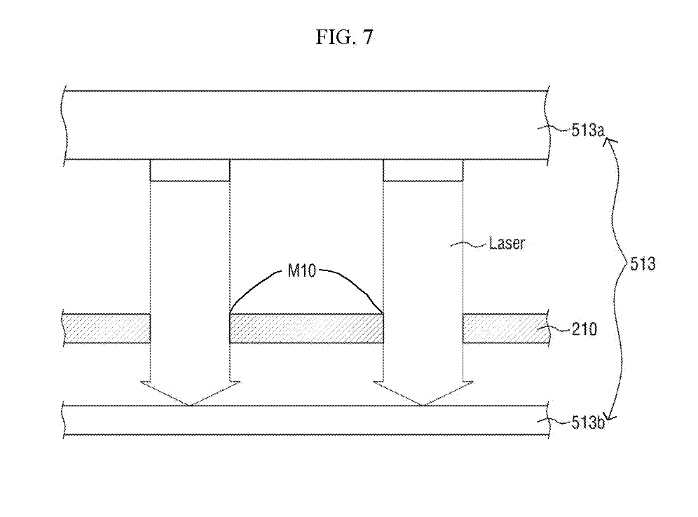

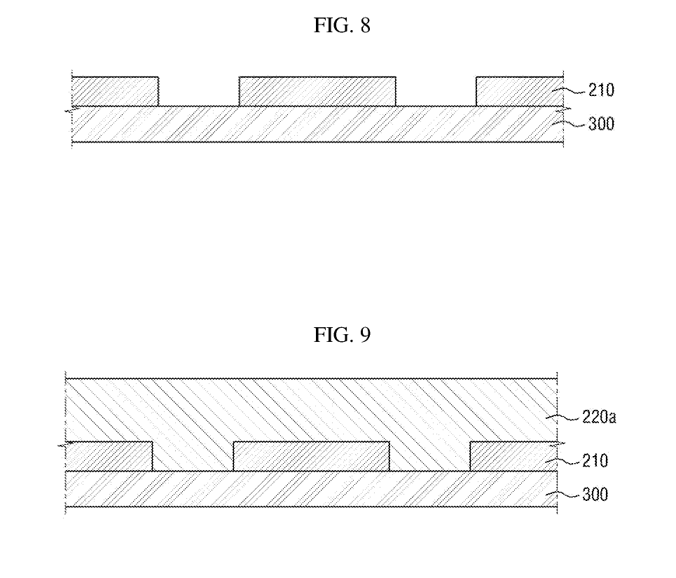

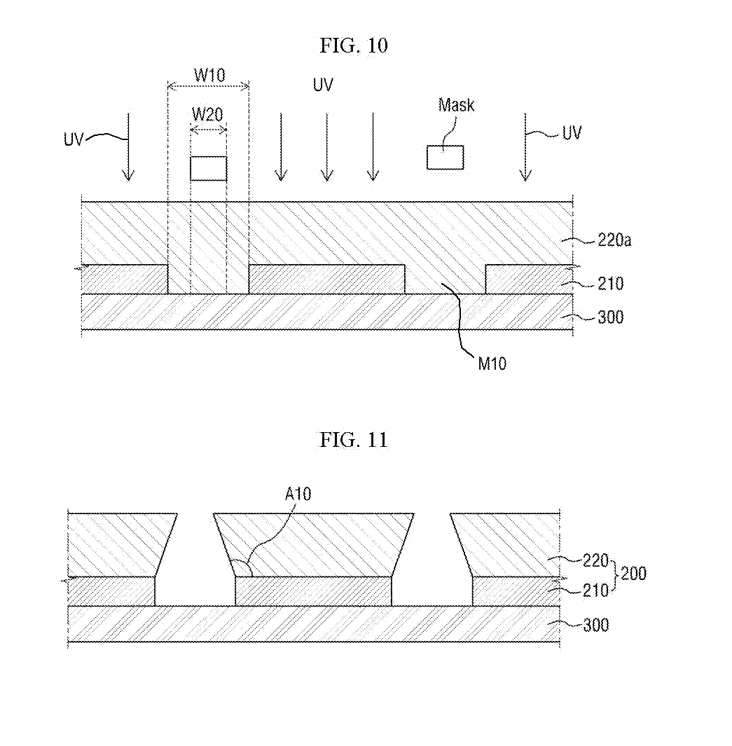

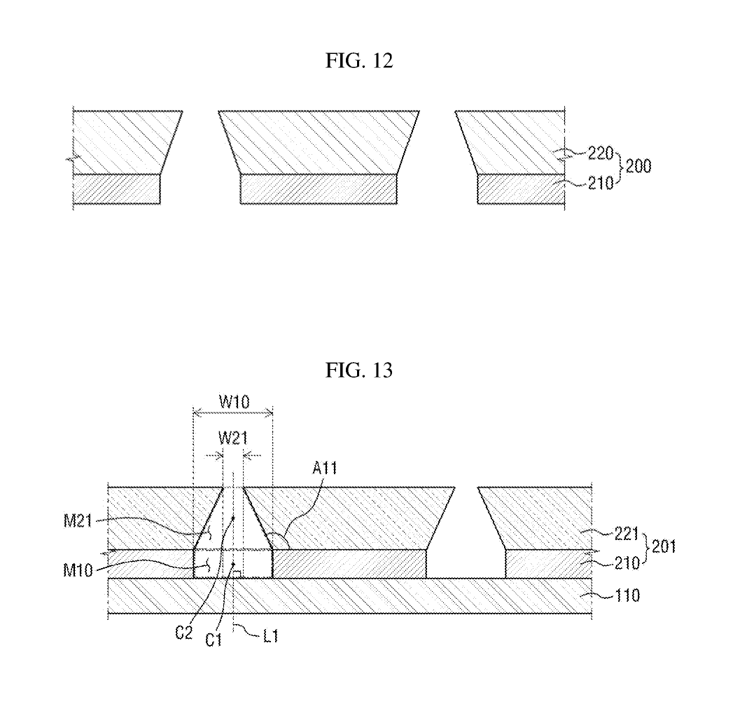

Hereinafter, referring to FIGS. 6 to 12, a method for manufacturing a pattern layer that is used in the method for manufacturing a donor substrate according to an embodiment of the present invention will be described in detail. FIG. 6 is a cross-sectional view illustrating an arrangement of a base film on a laser portion in a method for manufacturing a donor substrate according to an embodiment of the present invention. FIG. 7 is a cross-sectional view illustrating formation of a film pattern by irradiating a base film with laser in a method for manufacturing a donor substrate according to an embodiment of the present invention. FIG. 8 is a cross-sectional view illustrating an arrangement of a film pattern on an auxiliary film in a method for manufacturing a donor substrate according to an embodiment of the present invention. FIG. 9 is a cross-sectional view illustrating formation of a photoresist layer on a film pattern in a method for manufacturing a donor substrate according to an embodiment of the present invention. FIG. 10 is a cross-sectional view illustrating exposure of a photoresist layer in a method for manufacturing a donor substrate according to an embodiment of the present invention. FIG. 11 is a cross-sectional view illustrating formation of a photoresist pattern by developing an exposed photoresist layer in a method for manufacturing a donor substrate according to an embodiment of the present invention. FIG. 12 is a cross-sectional view illustrating a pattern layer, from which an auxiliary film is separated in a method for manufacturing a donor substrate according to an embodiment of the present invention. For convenience in explanation, in FIGS. 6 to 12, the same reference numerals are used for substantially the same elements illustrated in FIGS. 1 to 5, and a duplicate explanation thereof will be omitted.

First, referring to FIG. 6, in order to manufacture a pattern layer 200 according to an embodiment of the present invention, a laser portion 513 may be first arranged on a base film 210a.

The base film 210a is a mother film for forming the above-described pattern film, and may be made of the same material as the material of the film pattern 210 as described above.

The laser portion 513 may include a laser irradiation portion 513a and a laser absorption portion 513b. The laser irradiation portion 513a irradiates laser light at high energy density, and laser irradiated from the laser irradiation portion 513a may be a carbon dioxide laser or a YAG (Yttrium, Aluminum, and Garnet) laser. The laser absorption portion 513b may be arranged to face the laser irradiation portion 513a and may be made of a material that can absorb laser, for example, silicon, so that other portions are prevented from being polluted by the laser.

The base film 210a may be arranged between the laser irradiation portion 513a and the laser absorption portion 513b, and may be aligned so as to correspond to the shape of the pattern to be formed.

Next, referring to FIG. 7, after the laser portion 513 is arranged on the base film 210a, a plurality of first openings M10 may be formed by irradiating the base film 210a with laser. That is, the base film 210a may be modified into the film pattern 210. Here, since the base film 210a is made of plastic that has a low heat denaturation, only a portion to which the laser is incident may be modified, and the surroundings of the laser-incident portion may not be modified.

Next, referring to FIG. 8, after the film pattern 210 is formed, the film pattern 210 may be arranged on the auxiliary film 300. That is, the film pattern 210 and the auxiliary film 300 can be laminated. Here, the auxiliary film 300 may be made of the same material as the base film 210a, that is, plastic. The auxiliary film 300 can protect the film pattern 210 until the film pattern 210 is attached to the substrate 110. Furthermore, the auxiliary film 300 may prevent photoresist from flowing downward in the following photoresist application process. In this embodiment of the present invention, the method for manufacturing the pattern layer 200 using the auxiliary film 300 is described. However, the auxiliary film 300 may be omitted depending on the processing conditions.

Next, referring to FIG. 9, after the film pattern 210 is arranged on the auxiliary film 300, photoresist may be applied onto the film pattern 210. That is, a photoresist layer 220a may be formed on the film pattern 210. In an exemplary embodiment of the present invention, negative photoresist may be applied onto the film pattern 210. In order to accurately perform the following exposure process after applying the photoresist, the upper surface of the applied photoresist layer 220a may be planarized.

Next, referring to FIG. 10, after the photoresist layer 220a is formed on the film pattern 210, the photoresist layer 220a may be exposed. In this case, a mask is arranged in the center portion of the plurality of first openings M10, the mask having a width W20 that is smaller than the minimum width W10 of the plurality of openings M10. Then, the photoresist layer 220a that is exposed by the mask may be exposed by UV rays.

Next, referring to FIG. 11, after the photoresist layer 220a of FIG. 10 is exposed, the exposed photoresist layer 220a may be developed. The development of the photoresist layer 220a may be performed by making the photoresist layer 220a pass through a bath that includes a developer. In the case where the photoresist layer 220a is made of negative photoresist, the shape of the photoresist pattern 220 that remains after the development may be an inverse taper as shown in FIG. 11.

Next, referring to FIG. 12, the auxiliary film 300 of FIG. 11 may be separated after the photoresist layer 220a is developed. That is, the pattern layer 200 and the auxiliary film 300 may be delaminated. Since the function of the auxiliary film 300 is to protect the film pattern 210 until the film pattern 210 is attached to the substrate 110 or to prevent the photoresist from flowing downward in the photoresist application process, the auxiliary film 300 which has performed that function may be removed. The removed auxiliary film 300 may be collected and reused. As described above, by removing even the auxiliary film 300, the pattern layer 200, which is used in the method for manufacturing a donor substrate 100 according to an embodiment of the present invention, can be completed.

As described above, in the method for manufacturing a donor substrate 100 according to an embodiment of the present invention, since the fine organic film pattern 120 of FIG. 2 is formed on the substrate 110 in advance, the fine organic film pattern 120 can be formed on the transfer target substrate. Furthermore, since the minimum width W10 of the first opening M10 that is defined by the film pattern 210 is larger than the minimum width W20 of the second opening M20 that is defined by the photoresist pattern 220, the organic film pattern 120 is formed only in the center portion of the first opening M10, and thus the pattern layer 200 can be removed without damage to the organic film pattern 120 after the organic film pattern 120 is formed. Furthermore, since the film pattern 210 is made of a plastic material that is light and has high ductility and elasticity, the organic film pattern 120 can be easily processed, and it is easy to handle the organic film pattern 120 since its shape deformation is small. Furthermore, since the organic material is deposited on the substrate 110 in a state where the film pattern 210 comes into contact with one surface of the substrate 110, substrate drooping does not occur, and thus the organic film pattern 120 can be stably formed.

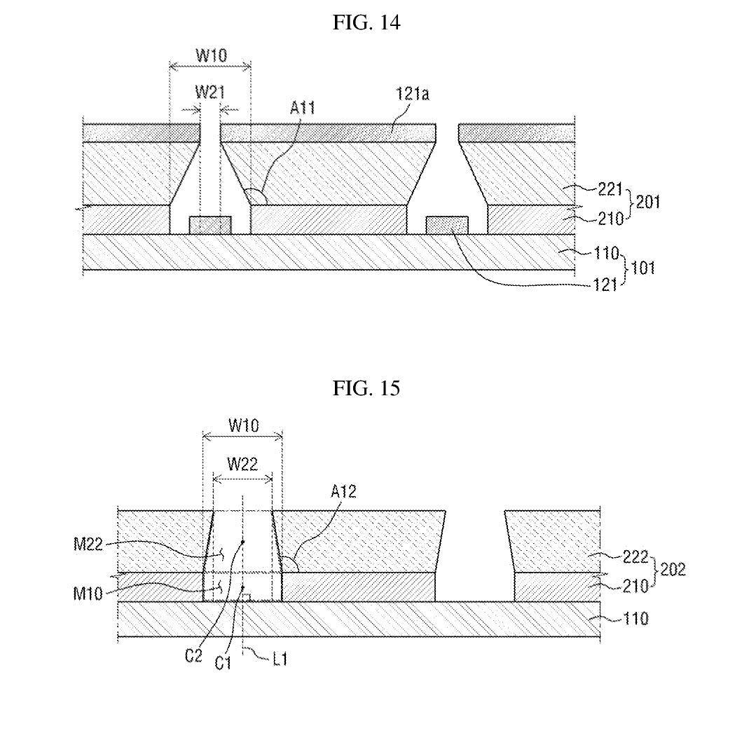

FIG. 13 is a planar view illustrating an arrangement of a pattern layer on a substrate in a method for manufacturing a donor substrate according to another embodiment of the present invention. FIG. 14 is a planar view illustrating formation of an organic film pattern on a surface of the substrate in a method for manufacturing a donor substrate according to another embodiment of the present invention. For convenience in explanation, in FIGS. 13 and 14, the same reference numerals are used for substantially the same elements as the elements illustrated in FIGS. 2 and 4, and the duplicate explanation thereof will be omitted.

Referring to FIGS. 13 and 14, according to the method for manufacturing a donor substrate 101 according to another embodiment of the present invention, when a photoresist pattern 221 that is included in a pattern layer 201 is formed, the angle that is formed between the one surface of the film pattern 210 and the side surface of the photoresist pattern 221 may be set to be larger. That is, the angle that is formed between the one surface of the film pattern 210 and the one surface of the photoresist pattern 221 in the pattern layer 201 that is used in the method for manufacturing a donor substrate 101 according to another embodiment of the present invention, that is, a second angle A11, may be larger than the angle that is formed between the one surface of the film pattern 210 and the one surface of the photoresist pattern 221 in the pattern layer 201 that is used in the method for manufacturing a donor substrate 100 according to an embodiment of the present invention, that is the first angle A10. Accordingly, the size of a second opening M21 can be reduced, and the minimum width of the second opening M21, that is, the second width W21, can be reduced. Thus, the width of the organic film pattern 121 that is deposited on the surface of the substrate 110 through the second opening M21 and the first opening M10 can be reduced, and the width of a sacrificial organic film pattern 121a that is formed on the photoresist pattern 221 can be increased.

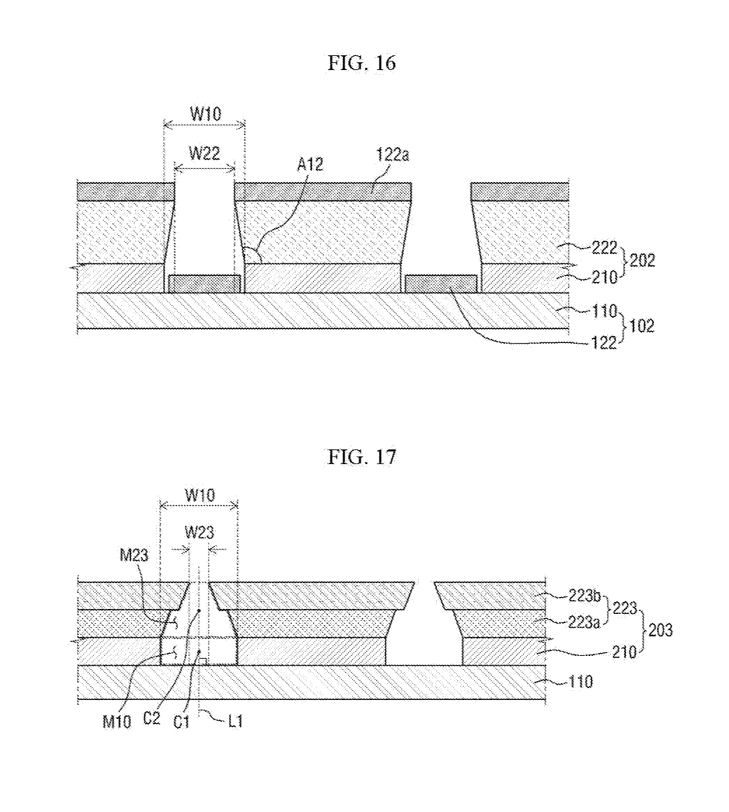

FIG. 15 is a planar view illustrating an arrangement of a pattern layer on a substrate in a method for manufacturing a donor substrate according to still another embodiment of the present invention. FIG. 16 is a planar view illustrating formation of an organic film pattern on a surface of the substrate in a method for manufacturing a donor substrate according to still another embodiment of the present invention. For convenience in explanation, in FIGS. 15 and 16, the same reference numerals are used for substantially the same elements as the elements illustrated in FIGS. 2 and 4, and the duplicate explanation thereof will be omitted.

Referring to FIGS. 15 and 16, according to the method for manufacturing a donor substrate 102 according to still another embodiment of the present invention, when a photoresist pattern 222 that is included in a pattern layer 202 is formed, the angle that is formed between the one surface of the film pattern 210 and the side surface of the photoresist pattern 222 may be set to be smaller. That is, the angle that is formed between the one surface of the film pattern 210 and the one surface of the photoresist pattern 222 in the pattern layer 202 that is used in the method for manufacturing a donor substrate 102 according to still another embodiment of the present invention, that is, a third angle A12, may be smaller than the angle that is formed between the one surface of the film pattern 210 and the one surface of the photoresist pattern 221 in the pattern layer 201 that is used in the method for manufacturing a donor substrate 100 according to an embodiment of the present invention, that is the first angle A10. Accordingly, the size of a second opening M22 can be increased, and the minimum width of the second opening M22, that is, the second width W22, can be increased. Thus, the width of the organic film pattern 122 that is deposited on the surface of the substrate 110 through the second opening M22 and the first opening M10 can be increased, and the width of a sacrificial organic film pattern 122a that is formed on the photoresist pattern 222 can be decreased.

As described above, according to the method for manufacturing a donor substrate 101 or 102 according to another embodiment and still another embodiment of the present invention illustrated in FIGS. 13 to 16, it is easy to change the minimum width of the opening that is defined by the photoresist pattern 221 or 222 by adjustment of the shape of the photoresist pattern 221 or 222, for example, by adjustment of the angle that is formed between the one surface of the film pattern 210 and the side surface of the photoresist pattern 221 or 222 with different processing conditions, and thus organic film patterns with various sizes can be manufactured in the single manufacturing line.

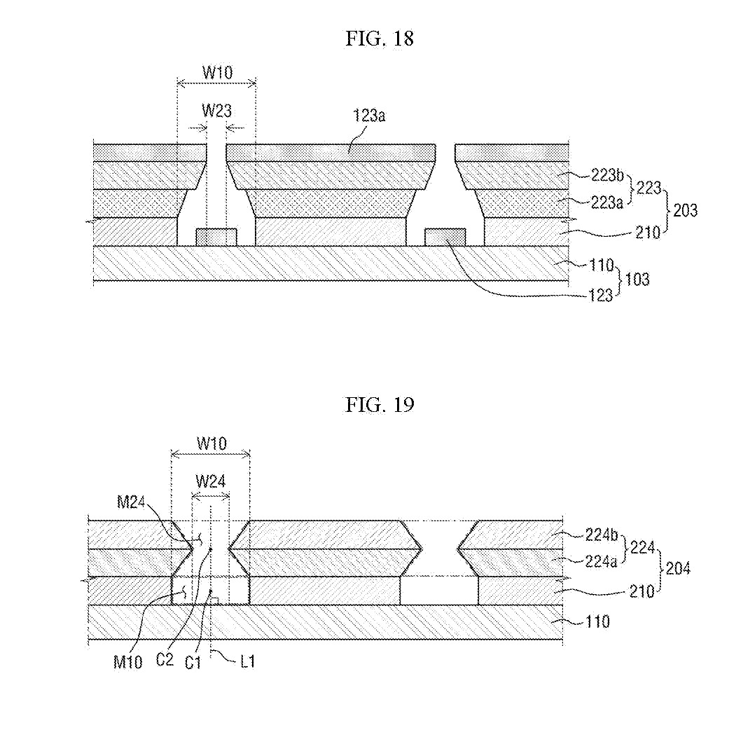

FIG. 17 is a planar view illustrating an arrangement of a pattern layer on a substrate in a method for manufacturing a donor substrate according to still another embodiment of the present invention. FIG. 18 is a planar view illustrating formation of an organic film pattern on a surface of the substrate in a method for manufacturing a donor substrate according to still another embodiment of the present invention. For convenience in explanation, in FIGS. 17 and 18, the same reference numerals are used for substantially the same elements as the elements illustrated in FIGS. 2 and 4, and the duplicate explanation thereof will be omitted.

Referring to FIGS. 17 and 18, in a pattern layer 203 that is used in the method for manufacturing a donor substrate 103 according to still another embodiment of the present invention, a plurality of photoresist patterns 223 may be configured. In an exemplary embodiment illustrated in the drawing, the photoresist patterns 223 may include a first photoresist pattern 223a that comes into contact with and is disposed on the film pattern 210 and a second photoresist pattern 223b that comes into contact with and is disposed on the first photoresist pattern 223a. Here, the center portion of the first potoresist pattern 223a may overlap the second photoresist pattern 223b, but the edge portion of the first photoresist pattern 223a may not overlap the second photoresist pattern 223b. Since the first photoresist pattern 223a and the second photoresist pattern 223b can be formed by separate exposures in separate exposure processes, they may be independent of each other. As described above, since the plurality of photoresist patterns 223 of various shapes are laminated, the shape of the second opening M23 and the minimum width of the second opening M23, that is, the second width W23, can be adjusted.

At least one of the plurality of layers that form the photoresist pattern 223 may have an inverse tapered shape. The first photoresist pattern 223a and the second photoresist pattern 223b illustrated in the drawing are in an inverse tapered shape, but the invention is not limited thereto. The first photoresist pattern 223a or the second photoresist pattern 223b may have a tapered shape. As described above, since at least one layer should have the inverse tapered shape, the minimum width of the second opening M23 that is defined by the photoresist pattern 223, that is, the second width W23, can be smaller than the minimum width of the first opening M10 that is defined by the film pattern 210, that is, the first width W10. Accordingly, the organic film pattern 123 may be positioned in the center portion of the surface of the substrate 110 that is exposed by the film pattern 210. That is, the organic film pattern 123 may be formed so as to be spaced apart from the film pattern 210. The sacrificial organic film pattern 123a may be formed on the second photoresist pattern 223b.

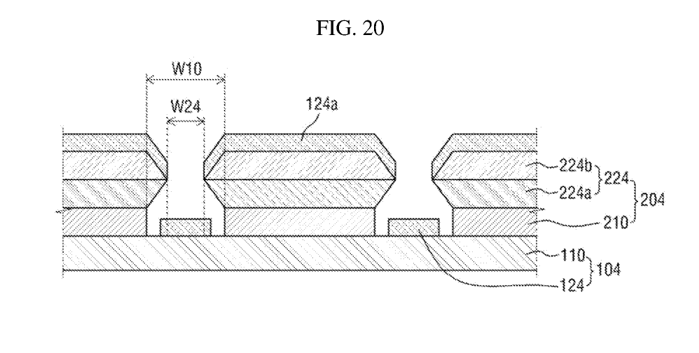

FIG. 19 is a planar view illustrating an arrangement of a pattern layer on a substrate in a method for manufacturing a donor substrate according to still another embodiment of the present invention. FIG. 20 is a planar view illustrating formation of an organic film pattern on a surface of the substrate in a method for manufacturing a donor substrate according to still another embodiment of the present invention. For convenience in explanation, in FIGS. 19 and 20, the same reference numerals are used for substantially the same elements as the elements illustrated in FIGS. 2 and 4, and the duplicate explanation thereof will be omitted.

Referring to FIGS. 19 and 20, in a pattern layer 204 that is used in the method for manufacturing a donor substrate 104 according to still another embodiment of the present invention, a plurality of photoresist patterns 224 may be configured. In an exemplary embodiment illustrated in the drawing, the photoresist patterns 224 may include a first photoresist pattern 224a that comes into contact with and is disposed on the film pattern 210 and a second photoresist pattern 224b that comes into contact with and is disposed on the first photoresist pattern 224a. Here, the first potoresist pattern 224a and the second photoresist pattern 224b may completely overlap each other. Furthermore, the first photoresist pattern 224a and the second photoresist pattern 224b may be symmetrically formed about an interface between the first photoresist pattern 224a and the second photoresist pattern 224b. Since the first photoresist pattern 224a and the second photoresist pattern 224b can be formed by separate exposures in separate exposure processes, they may be independent of each other. As described above, since the plurality of photoresist patterns 224 of various shapes are laminated, the shape of the second opening M24 and the minimum width of the second opening M24, that is, the second width W24, can be adjusted. In particular, the height at which the minimum width of the second opening M24 is formed can be adjusted.

At least one of the plurality of layers that form the photoresist pattern 224 may have an inverse tapered shape. In an exemplary embodiment of the present invention illustrated in the drawings, the first photoresist pattern 224a may have an inverse tapered shape, and the second photoresist pattern 224b may have the tapered shape, but the invention is not limited thereto. The first photoresist pattern 224a may have the tapered shape, and the second photoresist pattern 224b may have the inverse tapered shape. As described above, since at least one layer should have the inverse tapered shape, the minimum width of the second opening M24 that is defined by the photoresist pattern 224, that is, the second width W24, can be smaller than the minimum width of the first opening M10 that is defined by the film pattern 210, that is, the first width W10. Accordingly, the organic film pattern 124 may be positioned in the center portion of the surface of the substrate 110 that is exposed by the film pattern 210. That is, the organic film pattern 124 may be formed so as to be spaced apart from the film pattern 210. The sacrificial organic film pattern 124a may be formed on the second photoresist pattern 224b.

As described above, according to the method for manufacturing a donor substrate 103 or 104 according to still another embodiment of the present invention illustrated in FIGS. 17 to 20, it is easy to change the minimum width of the opening that is defined by the photoresist pattern 223 or 224 and the height at which the minimum width is formed by adjustment of the shape of the plurality of layers included in the photoresist pattern 223 or 224, and thus organic film patterns with various sizes can be manufactured in the single manufacturing line.

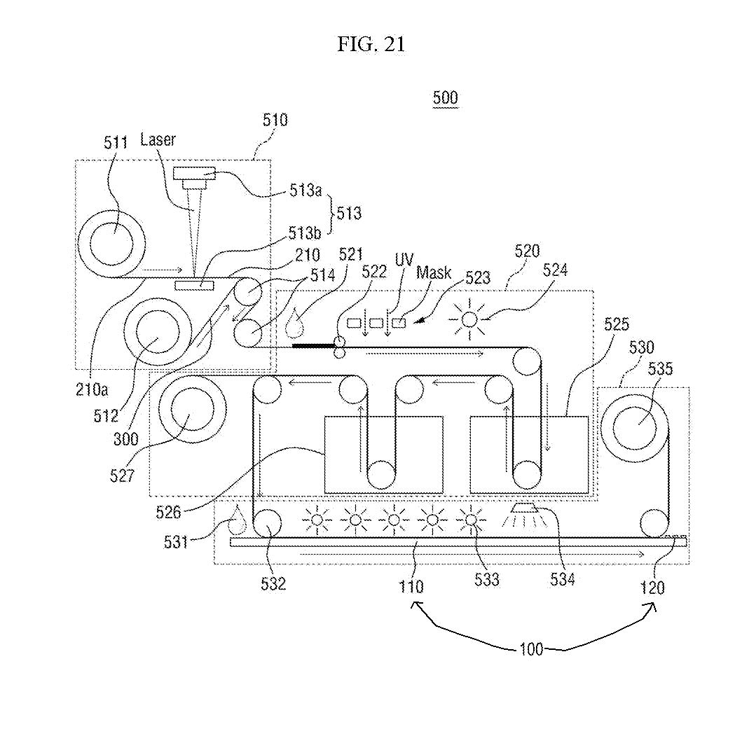

Hereinafter, referring to FIG. 21, an apparatus for manufacturing a donor substrate according to an embodiment of the present invention will be described. FIG. 21 is a conceptual view schematically illustrating an apparatus for manufacturing a donor substrate according to an embodiment of the present invention.

Referring to FIG. 21, an apparatus 500 for manufacturing a donor substrate according to an embodiment of the present invention may include a first patterning portion 510, a second patterning portion 520, and a third patterning portion 530.

The first patterning portion 510 may form a film pattern 210 that defines a plurality of first openings M10. The first patterning portion 510 may include a first unwind roll 511, a second unwind roll 512, a laser unit 513, and a first laminating roller 514.

The first unwind roll 511 may store the base film 210a in the form of a roll, and when the process of manufacturing a donor substrate 100 starts, the first unwind roll 511 may unwind the base film 210a stored in the form of a roll. As described above, it is preferable that the base film 210a be stored in the form of a roll, and be made of a material having high ductility and elasticity since the rolling, folding, or bending of the base film 210a is performed in the following process.

The second unwind roll 512 may store the auxiliary film 300 in the form of a roll, and when the process of manufacturing a donor substrate 100 starts, the second unwind roll 512 may unwind the auxiliary film 300 stored in the form of a roll. In the same manner as the base film 210a, it is preferable that the auxiliary film 300 be made of a material having high ductility and elasticity. In this embodiment of the present invention, the apparatus 500 for manufacturing a donor substrate 100 using the auxiliary film 300 is described. However, the auxiliary film 300 may not be used, and in the apparatus for manufacturing the donor substrate 100 that does not use the auxiliary film 300, a mechanism related to the auxiliary film 300, for example, the second unwind roll 512, may be omitted.

As described above, the laser portion 513 may include the laser irradiation portion 513a and the laser absorption portion 513b. The laser irradiation portion 513a of the laser portion 513 may form the plurality of first openings M10 of FIG. 7 by irradiation of the base film 210a of FIG. 6 with the laser so as to modify the base film 210a of FIG. 6 into the film pattern 210 of FIG. 21.

The first laminating roller 514 may laminate the film pattern 210 that has passed through the laser portion 513 and the unwound auxiliary film 300. In an exemplary embodiment of the present invention, the film pattern 210 and the auxiliary film 300 are compressed to fix the position of the film pattern 210 on the auxiliary film 300. In another exemplary embodiment of the present invention, the film pattern 210 and the auxiliary film 300 may be adhered to each other using adhesives. However, since the auxiliary film 300 is delaminated in the following process, it is preferable that he auxiliary film 300 be weakly adhered to the film pattern 210.

The second patterning portion may form the photoresist pattern 220 that defines the second openings M20, the minimum width W20 of which is smaller than the minimum width M10 of the first openings M10, on the film pattern 210 (see FIG. 10). The second patterning portion 520 may include a photoresist application portion 521, a smoothing roller 522, an exposure portion 523, a first heat curing portion 524, a development portion 525, a cleaning portion 526, and a first rewind roll 527.

The photoresist application portion 521 may apply the photoresist on the film pattern 210. That is, the photoresist layer 220a of FIG. 9 may be formed on the film pattern 210. In an exemplary embodiment of the present invention, the photoresist may be negative photoresist, but the invention is not limited thereto.

The smoothing roller 522 may smooth the upper surface of the photoresist layer 220a. That is, since there is a step height between a portion where the film pattern 210 is formed and a portion where the film pattern 210 is not formed, the photoresist layer 220a may be curved due to such a step height. Accordingly, in order to accurately perform the following exposure process by removal of the curved portion, the upper surface of the applied photoresist layer 220a may be planarized.

The exposure portion may expose the applied photoresist, that is, the photo resist layer 220a. In this case, after the mask of FIG. 21 is arranged, the portion of photoresist layer 220a that is exposed by the mask may be exposed to UV.

The first heat curing portion 524 of FIG. 21 may cure the exposed photoresist layer 220a by heat. In an exemplary embodiment of the present invention, although not illustrated, the photoresist layer 220a can be uniformly cured using a device, such as a hot plate or an oven. By curing the exposed and activated photoresist layer 220a by heat, the curing can be performed much more than the unexposed photoresist layer 220a.

The development portion 525 may form the photoresist pattern 220 by developing the exposed and heat-cured photoresist layer 220a. The development portion 525 may include a bath in which a developer is contained, and the unexposed photoresist layer 220a may be removed as the photoresist layer 220a passes through the bath. In an exemplary embodiment of the present invention, the photoresist layer 220a may be made of negative photoresist, and in this case, the photoresist pattern 220, which is formed by the developing portion 525, may have an inverse tapered shape.

The cleaning portion 526 may clean the developed and formed photoresist pattern 220. The cleaning portion 526 may include a bath that contains a cleaning solution, for example, ultra pure water, and the photoresist pattern 220 may be cleaned as it passes through the bath. The cleaning portion 526 may include a plurality of baths.

The first rewind roll 527 may delaminate and rewind the film pattern 210 on which the photoresist pattern 220 is formed and the auxiliary film 300. The rewound and collected auxiliary film 300 may be reused later.

The third patterning portion 530 may arrange the film pattern 210 on which the photoresist pattern 220 is formed on the substrate 110, and may deposit an organic material on the surface of the substrate 110 through the second opening M20 and the first opening M10. The third patterning portion 530 may include an adhesive application portion 531, a second laminating roller 532, a second heat curing portion 533, a deposition portion 534, and a second rewind roll 535.

The adhesive application portion 531 may apply adhesives for adhering the pattern layer 200 and the substrate 110 to each other. The adhesives may be adhesives that are specialized at plastic adhesion. That is, since the pattern layer 200 is separated from the substrate 110 in the following process, the applied adhesives may be attached to the film pattern 210 composed of plastic, and may be separated together with the pattern layer 200.

The second laminating roller 532 may laminate the film pattern 210 on which the photoresist pattern 220 is formed, that is, the pattern layer 200, on the substrate 110. That is, the pattern layer 200 may be aligned and attached to the substrate 110 so as to expose the surface of the substrate 110 on which the organic film pattern 120 is to be formed.

The second heat curing portion 533 may finally cure the applied adhesives by applying heat to the laminated pattern layer 200 and the substrate 110. That is, for safety in the following deposition process, the second heat curing portion 533 may cure the substrate 110 and attached materials with predetermined hardness.

The deposition portion 534 may form the organic film pattern 120 by depositing an organic material on the surface of the substrate 110. Although not illustrated in the drawing, the deposition portion 534 may include a vacuum chamber, and the organic material can be deposited in the vacuum chamber. Furthermore, it is illustrated that the organic material is deposited on the lower portion in the drawing. However, the deposition of the organic material is not limited thereto, and the organic material may be deposited on the upper portion.

The second rewind roll 535 may delaminate the pattern layer 200 that has passed through the deposition portion 534 from the substrate 110. That is, the pattern layer 200 may be collected by the second rewind roll 535. At least the film pattern 210 of the collected pattern layer 200 may be reused later.

The above-described first patterning portion 510, the second patterning portion 520, and the third patterning portion 530 may be connected in line. That is, by using the base film 210a and the auxiliary film 300 having high ductility and elasticity, a roll type processing can be performed.

As described above, according to the method for manufacturing a donor substrate according to an embodiment of the present invention, since the pattern layer 200 is formed by the successive in-line process and the organic film pattern 120 is formed on the substrate 110 using the pattern layer 200, an overall processing loss can be reduced. Furthermore, since a roll type processing procedure is possible, the size of the whole equipment is reduced and the efficiency in space can be heightened.

Although preferred embodiments of the present invention have been described for illustrative purposes, those skilled in the art will appreciate that various modifications, additions and substitutions are possible without departing from the scope and spirit of the present invention as recited in the accompanying claims.

What is claimed is:

1. A method for manufacturing a donor substrate, comprising the steps of:
arranging a pattern layer, which exposes a surface of a substrate, on the substrate; and
depositing an organic material on the exposed surface of the substrate;
wherein the pattern layer includes a film pattern that defines a plurality of first openings and a photoresist pattern that is positioned on the film pattern and defines second openings which correspond to the first openings, respectively, a minimum width of the second openings being smaller than a minimum width of the first openings.

2. The method for manufacturing a donor substrate of claim 1, wherein the second opening completely overlaps a corresponding first opening.

3. The method for manufacturing a donor substrate of claim 1, wherein an area in which said each second opening having the minimum width is vertically projected onto the substrate is positioned on an inner side relative to a boundary of said corresponding first opening.

4. The method for manufacturing a donor substrate of claim 1, wherein an area in which said each second opening having the minimum width is vertically projected onto the substrate is spaced apart from the film pattern.

5. The method for manufacturing a donor substrate of claim 1, wherein a line that connects a center of the first opening and a center of the second opening to each other is perpendicular to the surface of the substrate.

6. The method for manufacturing a donor substrate of claim 5, wherein a shape of the first opening and a shape of the second opening are substantially the same.

7. The method for manufacturing a donor substrate of claim 1, wherein the photoresist pattern has an inverse tapered shape.

8. The method for manufacturing a donor substrate of claim 1, wherein the photoresist pattern comprises:
a first photoresist pattern positioned on the film pattern; and
a second photoresist pattern positioned on the first photoresist pattern;
wherein at least one of the first photoresist pattern and the second photoresist pattern has an inverse tapered shape.

9. The method for manufacturing a donor substrate of claim 1, wherein the substrate is made of a material that can perform one of changing energy and converting energy.

10. A method for manufacturing a donor substrate, comprising the steps of:
forming a pattern layer which includes a film pattern that defines a plurality of openings and a photoresist pattern that is positioned on the film pattern and is has inverse tapered shape;
arranging the pattern layer on a substrate; and
depositing an organic material on a surface of the substrate which is exposed by the pattern layer.

11. The method for manufacturing a donor substrate of claim 10, wherein the step of forming the pattern layer comprises:
forming the film pattern by irradiating a base film with laser; and
forming the photoresist pattern having the inverse tapered shape on the film pattern using negative photoresist.

12. The method for manufacturing a donor substrate of claim 11, wherein the step of forming the pattern layer further comprises arranging the film pattern on an auxiliary film after forming the film pattern.

13. The method for manufacturing a donor substrate of claim 12, wherein the step of forming the pattern layer further comprises removing the auxiliary film after forming the photoresist pattern.

14. The method for manufacturing a donor substrate of claim 11, wherein the step of forming the photoresist pattern comprises:
applying negative photoresist on the film pattern;
arranging a mask on a center portion of the plurality of openings, the mask having a width that is smaller than a width of the plurality of openings;
exposing the negative photoresist that is exposed by the mask; and
developing the exposed photoresist.

15. The method for manufacturing a donor substrate of claim 10, wherein the step of forming the pattern layer comprises adjusting an angle that is formed between one surface of the film pattern and a side surface of the photoresist pattern.
